(19) United States
(12) Patent Application Publication
(10) Pub. No.: US 2015/0221801 A1
(43) Pub. Date: Aug. 6, 2015

(54) PHOTOELECTRIC CONVERSION ELEMENT AND METHOD OF MANUFACTURING PHOTOELECTRIC CONVERSION ELEMENT

(71) Applicant: SHARP KABUSHIKI KAISHA, Osaka-shi, Osaka (JP)

(72) Inventors: Yoshitaka Yamamoto, Osaka-shi (JP); Naoki Koide, Osaka-shi (JP)

(73) Assignee: Sharp Kabushiki Kaisha, Osaka-shi (JP)

(21) Appl. No.: 14/426,421

(22) PCT Filed: Sep. 9, 2013
(86) PCT No.: PCT/JP2013/074208

§ 371 Date: Mar. 6, 2015

(30) Foreign Application Priority Data
Sep. 12, 2012 (JP) 2012-200239

(51) Int. Cl. H01L 31/075; H01L 31/0376; H01L 31/20

(52) U.S. Cl. CPC H01L 31/075; H01L 31/20; H01L 31/0376

(57) ABSTRACT

A photoelectric conversion element including an i-type non-single-crystal film provided on the entire one surface of a semiconductor substrate, in which an interface between the semiconductor substrate and the i-type non-single-crystal film is flat, and a method of manufacturing the photoelectric conversion element are provided.

### TECHNICAL FIELD

The present invention relates to a photoelectric conversion element and a method of manufacturing a photoelectric conversion element.

### BACKGROUND ART

Solar cells directly converting solar energy to electric energy have recently increasingly been expected as a next-generation energy source particularly from a point of view of global environmental issues. Various types of solar cells such as solar cells composed of a compound semiconductor or solar cells composed of an organic material have been available, and solar cells composed of silicon crystals have currently been in the mainstream.

Solar cells which have currently been manufactured and marketed in a largest number have such a structure that an electrode is formed on each of a light-receiving surface which is a surface on a solar ray incident side and a back surface opposite to the light-receiving surface.

When an electrode is formed on a light-receiving surface, however, the electrode reflects and absorbs solar rays, which leads to decrease in an amount of incident solar rays in correspondence with an area occupied by the electrode. Therefore, a solar cell (a hetero junction back contact cell) having improved characteristics by forming a stack of an i-type amorphous silicon film and a p-type amorphous silicon film and a stack of an i-type amorphous silicon film and an n-type amorphous silicon film on a back surface of an n-type single crystal silicon substrate and forming electrodes on the p-type amorphous silicon film and the n-type amorphous silicon film of these stacks for improvement of characteristics have increasingly been developed (see, for example, PTD 1).

### CITATION LIST

### Patent Document

### PTD 1: Japanese Patent Laying-Open No. 2010-80887

### SUMMARY OF INVENTION

### Technical Problem

One example of a method of manufacturing a hetero junction back contact cell will be described below with reference to schematic cross-sectional views in FIGS. 13 to 29. Initially, as shown in FIG. 13, an a-Si (i/p) layer 102 obtained by stacking an i-type amorphous silicon film and a p-type amorphous silicon film in this order is formed on a back surface of a c-Si (n) substrate 101 composed of n-type single crystal silicon, on which light-receiving surface a textured structure (not shown) has been formed.

Then, as shown in FIG. 14, an a-Si (i/n) layer 103 obtained by stacking an i-type amorphous silicon film and an n-type amorphous silicon film in this order is formed on a light-receiving surface of c-Si (n) substrate 101.

Then, as shown in FIG. 15, a photoresist film 104 is formed on a back surface of a part of a-Si (i/p) layer 102. Here, photoresist film 104 is formed by applying a photoresist on the entire back surface of a-Si (i/p) layer 102 and thereafter patterning the photoresist with an exposure technique and a development technique.

Then, as shown in FIG. 16, the back surface of c-Si (n) substrate 101 is exposed by etching a part of a-Si (i/p) layer 102 with photoresist film 104 serving as a mask.

Then, after photoresist film 104 is removed as shown in FIG. 17, an a-Si (i/n) layer 105 obtained by stacking an i-type amorphous silicon film and an n-type amorphous silicon film in this order is formed as shown in FIG. 18 so as to cover the back surface of a-Si (i/p) layer 102 exposed as a result of removal of photoresist film 104 and the back surface of c-Si (n) substrate 101 exposed as a result of etching.

Then, as shown in FIG. 19, a photoresist film 106 is formed on a back surface of a part of a-Si (i/n) layer 105. Here, photoresist film 106 is formed by applying a photoresist on the entire back surface of a-Si (i/n) layer 105 and thereafter patterning the photoresist with the exposure technique and the development technique.

Then, as shown in FIG. 20, the back surface of a-Si (i/p) layer 102 is exposed by etching a part of a-Si (i/n) layer 105 with photoresist film 106 serving as a mask.

Then, after photoresist film 106 is removed as shown in FIG. 21, a transparent conductive oxide film 107 is formed as shown in FIG. 22 so as to cover the back surface of a-Si (i/n) layer 105 exposed as a result of removal of photoresist film 106 and the back surface of a-Si (i/p) layer 102 exposed as a result of etching.

Then, as shown in FIG. 23, a photoresist film 108 is formed on a back surface of a part of transparent conductive oxide film 107. Here, photoresist film 108 is formed by applying a photoresist on the entire back surface of transparent conductive oxide film 107 and thereafter patterning the photoresist with the exposure technique and the development technique.

Then, as shown in FIG. 24, the back surfaces of a-Si (i/p) layer 102 and a-Si (i/n) layer 105 are exposed by etching a part of transparent conductive oxide film 107 with photoresist film 108 serving as a mask.

Then, after photoresist film 108 is removed as shown in FIG. 25, a photoresist film 109 is formed as shown in FIG. 26 so as to cover the exposed back surfaces of a-Si (i/p) layer 102 and a-Si (i/n) layer 105 and the back surface of a part of transparent conductive oxide film 107. Here, photoresist film 109 is formed by applying a photoresist on the exposed back surfaces of a-Si (i/p) layer 102 and a-Si (i/n) layer 105 and the entire back surface of transparent conductive oxide film 107 and thereafter patterning the photoresist with the exposure technique and the development technique.

Then, as shown in FIG. 27, a back electrode layer 110 is formed on the entire back surfaces of transparent conductive oxide film 107 and photoresist film 109.

Then, as shown in FIG. 28, photoresist film 109 and back electrode layer 110 are removed through lift-off such that back electrode layer 110 is left only on a part of the surface of transparent conductive oxide film 107.

Then, as shown in FIG. 29, an anti-reflection coating 111 is formed on a surface of a-Si (i/n) layer 103. The hetero junction back contact cell is completed as above.

In a method of manufacturing a hetero junction back contact cell above, as shown in FIGS. 13 to 16, the back surface of c-Si (n) substrate 101 is exposed by etching a part of a-Si (i/p) layer 102 after a-Si (i/p) layer 102 is formed on the back surface of c-Si (n) substrate 101.

When the back surface of c-Si (n) substrate 101 is exposed, however, the exposed back surface of c-Si (n) substrate 101 will be contaminated. Therefore, disadvantageously, carriers tend to be captured at an interface between the back surface of c-Si (n) substrate 101 and a-Si (i/n) layer 105, lifetime of the carriers is shortened, and characteristics of the hetero junction back contact cell are lowered.

In view of the circumstances above, an object of the present invention is to provide a photoelectric conversion element capable of achieving improvement in characteristics of a hetero junction back contact cell and a method of manufacturing a photoelectric conversion element.

### Solution to Problem

The present invention is directed to a photoelectric conversion element including a semiconductor substrate of a first conductivity type, an i-type non-single-crystal film provided on the entire one surface of the semiconductor substrate, a non-single-crystal film of the first conductivity type provided on a surface of a part of the i-type non-single-crystal film, a non-single-crystal film of a second conductivity type provided on the surface of another part of the i-type non-single-crystal film, an electrode for the first conductivity type provided on the non-single-crystal film of the first conductivity type, and an electrode for the second conductivity type provided on the non-single-crystal film of the second conductivity type, an interface between the semiconductor substrate and the i-type non-single-crystal film being flat.

Here, in the photoelectric conversion element according to the present invention, preferably, the i-type non-single-crystal film is an i-type amorphous film.

In the photoelectric conversion element according to the present invention, preferably, a maximum height difference in a proximate region around the interface between the semiconductor substrate and the i-type non-single-crystal film is smaller than 1 μm.

In the photoelectric conversion element according to the present invention, preferably, the i-type non-single-crystal film between the non-single-crystal film of the first conductivity type and the semiconductor substrate is different in film thickness from the i-type non-single-crystal film between the non-single-crystal film of the second conductivity type and the semiconductor substrate.

In the photoelectric conversion element according to the present invention, preferably, the i-type non-single-crystal film between the non-single-crystal film of the first conductivity type and the semiconductor substrate is smaller in film thickness than the i-type non-single-crystal film between the non-single-crystal film of the second conductivity type and the semiconductor substrate.

Furthermore, the present invention is directed to a method of manufacturing a photoelectric conversion element, including the steps of stacking an i-type non-single-crystal film on the entire one surface of a semiconductor substrate of a first conductivity type, stacking a non-single-crystal film of a second conductivity type on a surface of the i-type non-single-crystal film, placing a mask material on a surface of a part of the non-single-crystal film of the second conductivity type, removing the non-single-crystal film of the second conductivity type exposed through the mask material such that at least a part of the i-type non-single-crystal film is left, forming a non-single-crystal film of the first conductivity type on the surface of the non-single-crystal film of the second conductivity type and on the surface of the i-type non-single-crystal film, removing the non-single-crystal film of the first conductivity type on the surface of the non-single-crystal film of the second conductivity type such that a part of the non-single-crystal film of the first conductivity type is left on the surface of the i-type non-single-crystal film, and forming an electrode layer on the surface of the non-single-crystal film of the first conductivity type and on the surface of the non-single-crystal film of the second conductivity type.

Here, in the method of manufacturing a photoelectric conversion element according to the present invention, preferably, the step of removing the non-single-crystal film of the first conductivity type is performed with wet etching using an alkali solution.

In the method of manufacturing a photoelectric conversion element according to the present invention, preferably, the step of stacking an i-type non-single-crystal film is performed only once.

In the method of manufacturing a photoelectric conversion element according to the present invention, preferably, the i-type non-single-crystal film is an i-type amorphous film.

In the method of manufacturing a photoelectric conversion element according to the present invention, preferably, in the step of stacking an i-type non-single-crystal film, the i-type non-single-crystal film is formed on the flat surface of the semiconductor substrate.

### Advantageous Effects of Invention

According to the present invention, a photoelectric conversion element capable of achieving improvement in characteristics of a hetero junction back contact cell and a method of manufacturing a photoelectric conversion element can be provided.

### BRIEF DESCRIPTION OF DRAWINGS

FIG. 1 is a schematic cross-sectional view of a hetero junction back contact cell in an embodiment.

FIG. 2 is a schematic enlarged cross-sectional view of one example of an interface between a semiconductor substrate and an i-type non-single-crystal film of the hetero junction back contact cell in the embodiment.

FIG. 3 is a schematic cross-sectional view illustrating a part of steps in one example of a method of manufacturing a hetero junction back contact cell in the embodiment.

FIG. 4 is a schematic cross-sectional view illustrating a part of steps in one example of the method of manufacturing a hetero junction back contact cell in the embodiment.

FIG. 5 is a schematic cross-sectional view illustrating a part of steps in one example of the method of manufacturing a hetero junction back contact cell in the embodiment.

FIG. 6 is a schematic cross-sectional view illustrating a part of steps in one example of the method of manufacturing a hetero junction back contact cell in the embodiment.

FIG. 7 is a schematic cross-sectional view illustrating a part of steps in one example of the method of manufacturing a hetero junction back contact cell in the embodiment.

FIG. 8 is a schematic cross-sectional view illustrating a part of steps in one example of the method of manufacturing a hetero junction back contact cell in the embodiment.

FIG. 9 is a schematic cross-sectional view illustrating a part of steps in one example of the method of manufacturing a hetero junction back contact cell in the embodiment.

FIG. 10 is a schematic cross-sectional view illustrating a part of steps in one example of the method of manufacturing a hetero junction back contact cell in the embodiment.

FIG. 11 is a schematic cross-sectional view illustrating a part of steps in one example of the method of manufacturing a hetero junction back contact cell in the embodiment.

FIG. 12 is a schematic cross-sectional view illustrating a part of steps in one example of the method of manufacturing a hetero junction back contact cell in the embodiment.

FIG. 13 is a schematic cross-sectional view illustrating one example of a method of manufacturing a hetero junction back contact cell.

FIG. 14 is a schematic cross-sectional view illustrating one example of the method of manufacturing a hetero junction back contact cell.

FIG. 15 is a schematic cross-sectional view illustrating one example of the method of manufacturing a hetero junction back contact cell.

FIG. 16 is a schematic cross-sectional view illustrating one example of the method of manufacturing a hetero junction back contact cell.

FIG. 17 is a schematic cross-sectional view illustrating one example of the method of manufacturing a hetero junction back contact cell.

FIG. 18 is a schematic cross-sectional view illustrating one example of the method of manufacturing a hetero junction back contact cell.

FIG. 19 is a schematic cross-sectional view illustrating one example of the method of manufacturing a hetero junction back contact cell.

FIG. 20 is a schematic cross-sectional view illustrating one example of the method of manufacturing a hetero junction back contact cell.

FIG. 21 is a schematic cross-sectional view illustrating one example of the method of manufacturing a hetero junction back contact cell.

FIG. 22 is a schematic cross-sectional view illustrating one example of the method of manufacturing a hetero junction back contact cell.

FIG. 23 is a schematic cross-sectional view illustrating one example of the method of manufacturing a hetero junction back contact cell.

FIG. 24 is a schematic cross-sectional view illustrating one example of the method of manufacturing a hetero junction back contact cell.

FIG. 25 is a schematic cross-sectional view illustrating one example of the method of manufacturing a hetero junction back contact cell.

FIG. 26 is a schematic cross-sectional view illustrating one example of the method of manufacturing a hetero junction back contact cell.

FIG. 27 is a schematic cross-sectional view illustrating one example of the method of manufacturing a hetero junction back contact cell.

FIG. 28 is a schematic cross-sectional view illustrating one example of the method of manufacturing a hetero junction back contact cell.

FIG. 29 is a schematic cross-sectional view illustrating one example of the method of manufacturing a hetero junction back contact cell.

### DESCRIPTION OF EMBODIMENTS

An embodiment of the present invention will be described below. In the drawings of the present invention, the same or corresponding elements have the same reference characters allotted.

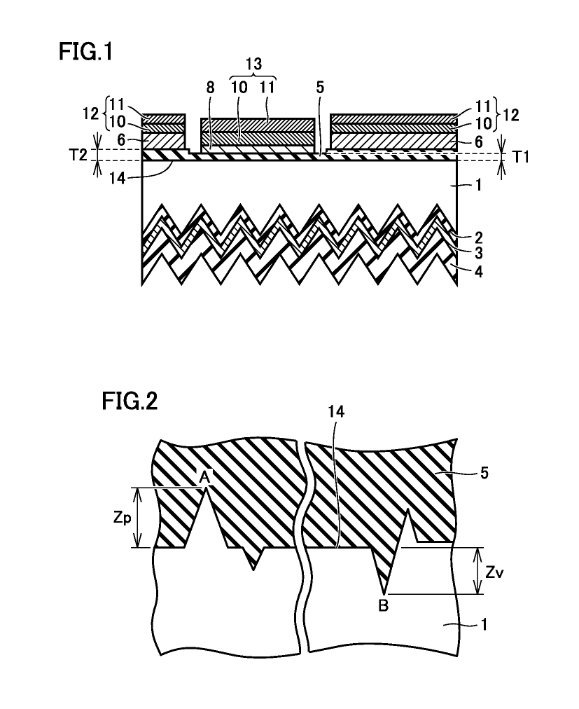

FIG. 1 shows a schematic cross-sectional view of a hetero junction back contact cell in an embodiment, which represents one example of a photoelectric conversion element according to the present invention. The hetero junction back contact cell in the embodiment includes a semiconductor substrate 1 composed of n-type single crystal silicon and an i-type non-single-crystal film 5 composed of i-type amorphous silicon provided on the entire back surface which is one surface of semiconductor substrate 1.

A non-single-crystal film 6 of a second conductivity type composed of p-type amorphous silicon is provided on a region of a part of a back surface of i-type non-single-crystal film 5 provided on the entire back surface of semiconductor substrate 1. A non-single-crystal film 8 of a first conductivity type composed of n-type amorphous silicon is provided on a region of another part of the back surface of i-type non-single-crystal film 5.

Here, a film thickness T1 of i-type non-single-crystal film 5 between semiconductor substrate 1 and non-single-crystal film 8 of the first conductivity type is different from a film thickness T2 of i-type non-single-crystal film 5 between semiconductor substrate 1 and non-single-crystal film 6 of the second conductivity type, and film thickness T1 is smaller than film thickness T2.

Film thickness T1 of i-type non-single-crystal film 5 between semiconductor substrate 1 and non-single-crystal film 8 of the first conductivity type can be, for example, not smaller than 3 nm and not greater than 6 nm, and film thickness T2 of i-type non-single-crystal film 5 between semiconductor substrate 1 and non-single-crystal film 6 of the second conductivity type can be, for example, not smaller than 5 nm and not greater than 10 nm.

An electrode 13 for the first conductivity type obtained by stacking a first electrode layer 10 and a second electrode layer 11 in this order is provided on non-single-crystal film 8 of the first conductivity type. An electrode 12 for the second conductivity type obtained by stacking first electrode layer 10 and second electrode layer 11 in this order is provided on non-single-crystal film 6 of the second conductivity type.

A stack of non-single-crystal film 8 of the first conductivity type and electrode 13 for the first conductivity type and a stack of non-single-crystal film 6 of the second conductivity type and electrode 12 for the second conductivity type are provided on the back surface of i-type non-single-crystal film 5 at a prescribed interval from each other.

A textured structure is formed on the entire light-receiving surface which is the other surface of semiconductor substrate 1 (a surface opposite to the back surface). A second i-type non-single-crystal film 2 composed of i-type amorphous silicon is provided on the entire light-receiving surface of semiconductor substrate 1, and a second non-single-crystal film 3 of the first conductivity type composed of n-type amorphous silicon is provided on second i-type non-single-crystal film 2. Furthermore, an anti-reflection coating 4 is provided on second non-single-crystal film 3 of the first conductivity type.

In the hetero junction back contact cell in the embodiment, an interface 14 between semiconductor substrate 1 and i-type non-single-crystal film 5 is flat. Here, “flat” herein means that a maximum height difference (Zp+Zv) representing a total distance between an A point having a maximum height Zp vertically above and a B point having a maximum height Zv vertically below, which points are located in a proximate region around interface 14, is smaller than 1 μm as shown, for example, in the schematic enlarged cross-sectional view in FIG. 2. The “proximate region around the interface between the semiconductor substrate and the i-type non-single-crystal film” herein means any such region that a horizontal interval in the interface between the semiconductor substrate and the i-type non-single-crystal film is not greater than 10 μm, and hence a horizontal interval between the A point and the B point is not greater than 10 μm.

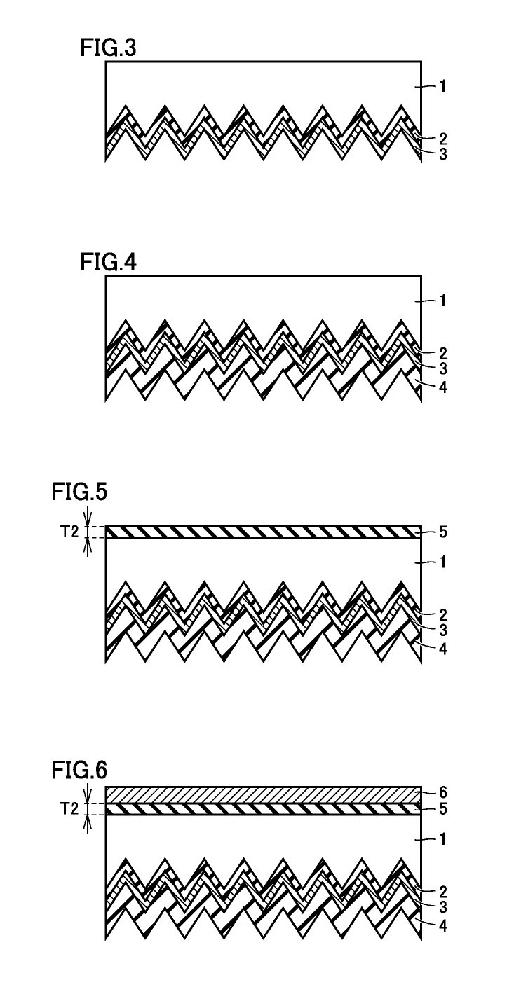

One example of a method of manufacturing the hetero junction back contact cell in the embodiment will be described below with reference to schematic cross-sectional views in FIGS. 3 to 12. Initially, as shown in FIG. 3, second i-type non-single-crystal film 2 composed of i-type amorphous silicon and second non-single-crystal film 3 of the first conductivity type composed of n-type amorphous silicon are stacked in this order, for example, with plasma chemical vapor deposition (CVD) on the light-receiving surface of semiconductor substrate 1 having the textured structure formed. Here, the step of forming second non-single-crystal film 3 of the first conductivity type may be omitted.

Semiconductor substrate 1 is not limited to a substrate composed of n-type single crystal silicon, and for example, a conventionally known semiconductor substrate may be employed. A textured structure on the light-receiving surface of semiconductor substrate 1 can be formed, for example, with texture-etching of the entire light-receiving surface of semiconductor substrate 1.

Though a thickness of semiconductor substrate 1 is not particularly limited, it can be, for example, not smaller than 50 μm and not greater than 300 μm and preferably not smaller than 100 μm and not greater than 200 μm. Though resistivity of semiconductor substrate 1 is not particularly limited either, it can be, for example, not lower than 0.1 Ω·cm and not higher than 10 Ω·cm.

Second i-type non-single-crystal film 2 is not limited to that of i-type amorphous silicon so long as it is not a single crystal film, and for example, a polycrystalline film, a microcrystalline film, or an amorphous film of the i-type which has conventionally been known can be employed. Though a film thickness of second i-type non-single-crystal film 2 is not particularly limited, it can be, for example, not smaller than 3 nm and not greater than 10 nm.

Second non-single-crystal film 3 of the first conductivity type is not limited to that of n-type amorphous silicon so long as it is not a single crystal film, and for example, a polycrystalline film, a microcrystalline film, or an amorphous film of the n-type which has conventionally been known can be employed. Though a film thickness of second non-single-crystal film 3 of the first conductivity type is not particularly limited, it can be, for example, not smaller than 5 nm and not greater than 10 nm.

For example, phosphorus can be employed as an n-type impurity to be contained in second non-single-crystal film 3 of the first conductivity type, and a concentration of the n-type impurity in second non-single-crystal film 3 of the first conductivity type can be, for example, approximately 5×10¹⁹/cm³.

The “i-type” herein means that intentionally no n-type or p-type impurity is doped, and the n or p conductivity type may be exhibited, for example, because of inevitable diffusion of an n-type or p-type impurity after fabrication of the hetero junction back contact cell.

“Amorphous silicon” herein encompasses also amorphous silicon in which a dangling bond of a silicon atom is terminated with hydrogen, such as hydrogenated amorphous silicon.

Then, as shown in FIG. 4, anti-reflection coating 4 is stacked on the entire surface of second non-single-crystal film 3 of the first conductivity type, for example, with sputtering or plasma CVD.

For example, a silicon nitride film can be employed as anti-reflection coating 4, and anti-reflection coating 4 can have a film thickness, for example, of approximately 100 nm.

Then, as shown in FIG. 5, i-type non-single-crystal film 5 composed of i-type amorphous silicon is stacked on the entire back surface of semiconductor substrate 1, for example, with plasma CVD. Here, the back surface of semiconductor substrate 1 on which i-type non-single-crystal film 5 is stacked is flat. For example, a method of physically polishing a surface of a wafer obtained by cutting a semiconductor single crystal ingot into thin slices, a chemical etching method, or a method based on combination thereof can be employed as a method of planarizing the back surface of semiconductor substrate 1.

I-type non-single-crystal film 5 is not limited to that of i-type amorphous silicon so long as it is not a single crystal film, and for example, a polycrystalline film, a microcrystalline film, or an amorphous film of the i-type which has conventionally been known can be employed. Though film thickness T2 of i-type non-single-crystal film 5 is not particularly limited, it can be, for example, not smaller than 5 nm and not greater than 10 nm.

Then, as shown in FIG. 6, non-single-crystal film 6 of the second conductivity type composed of p-type amorphous silicon is stacked on the back surface of i-type non-single-crystal film 5, for example, with plasma CVD.

Non-single-crystal film 6 of the second conductivity type is not limited to that of p-type amorphous silicon so long as it is not a single crystal film, and for example, a polycrystalline film, a microcrystalline film, or an amorphous film of the p-type which has conventionally been known can be employed. Though a film thickness of non-single-crystal film 6 of the second conductivity type is not particularly limited, it can be, for example, not smaller than 5 nm and not greater than 20 nm.

For example, boron can be employed as a p-type impurity to be contained in non-single-crystal film 6 of the second conductivity type, and a concentration of the p-type impurity in non-single-crystal film 6 of the second conductivity type can be, for example, approximately 5×10¹⁹/cm³.

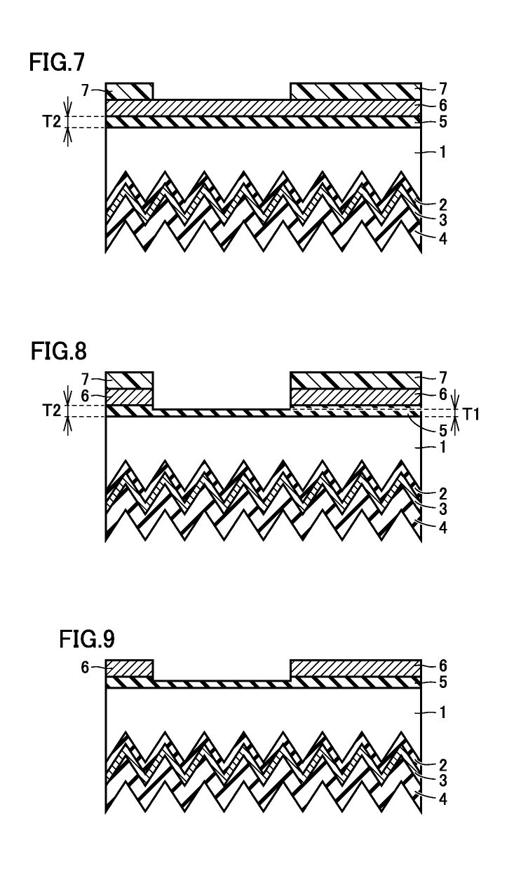

Then, as shown in FIG. 7, a mask material 7 is disposed on a back surface of a part of non-single-crystal film 6 of the second conductivity type.

Here, an acid-resistant resist capable of deterring etching with the use of an acid solution which will be described later is employed as mask material 7. A conventionally known acid-resistant resist can be employed as the acid-resistant resist, without particularly being limited.

Though a method of disposing mask material 7 is not particularly limited, when mask material 7 is made of an acid-resistant resist, mask material 7 can be disposed on the back surface of a part of non-single-crystal film 6 of the second conductivity type, for example, by applying mask material 7 on the entire back surface of non-single-crystal film 6 of the second conductivity type and thereafter patterning mask material 7 with the exposure technique and the development technique.

Then, as shown in FIG. 8, non-single-crystal film 6 of the second conductivity type exposed through mask material 7 is removed such that at least a part of i-type non-single-crystal film 5 is left.

Here, non-single-crystal film 6 of the second conductivity type is preferably removed, for example, by etching with the use of an acid solution. Since an acid solution can accurately control a rate of etching of a non-single-crystal film of amorphous silicon or the like, non-single-crystal film 6 of the second conductivity type can accurately be removed.

For example, a liquid mixture of hydrofluoric acid and a hydrogen peroxide solution, a liquid mixture of hydrofluoric acid and ozone water, hydrofluoric acid containing ozone micronano bubbles, or a liquid mixture of hydrofluoric acid and nitric acid diluted with water can be employed as the acid solution.

In removing non-single-crystal film 6 of the second conductivity type, a part of i-type non-single-crystal film 5 may be removed so long as i-type non-single-crystal film 5 covers the entire back surface of semiconductor substrate 1, and film thickness T1 of i-type non-single-crystal film 5 after removal can be, for example, not smaller than 3 nm and not greater than 6 nm.

Then, as shown in FIG. 9, the back surface of non-single-crystal film 6 of the second conductivity type is exposed by removing mask material 7.

Though a method of removing mask material 7 is not particularly limited, when mask material 7 is made of an acid-resistant resist, mask material 7 can be removed, for example, by dissolving mask material 7 in acetone.

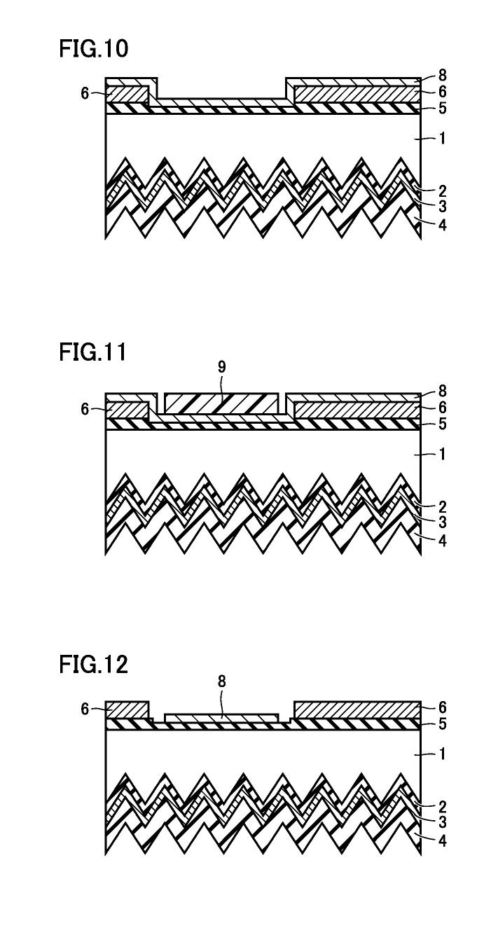

Then, as shown in FIG. 10, non-single-crystal film 8 of the first conductivity type composed of n-type amorphous silicon is stacked, for example, with plasma CVD, so as to cover the back surface of non-single-crystal film 6 of the second conductivity type and the back surface of i-type non-single-crystal film 5 exposed through non-single-crystal film 6 of the second conductivity type.

Non-single-crystal film 8 of the first conductivity type is not limited to that of n-type amorphous silicon so long as it is not a single crystal film, and for example, a polycrystalline film, a microcrystalline film, or an amorphous film of the n-type which has conventionally been known can be employed. Though a film thickness of non-single-crystal film 8 of the first conductivity type is not particularly limited, it can be, for example, not smaller than 5 nm and not greater than 10 nm.

For example, phosphorus can be employed as an n-type impurity to be contained in non-single-crystal film 8 of the first conductivity type, and a concentration of the n-type impurity in non-single-crystal film 8 of the first conductivity type can be, for example, approximately 5×10¹⁹/cm³.

Then, as shown in FIG. 11, a second mask material 9 is disposed on a back surface of a part of non-single-crystal film 8 of the first conductivity type. Here, second mask material 9 is disposed on a part of a region of non-single-crystal film 8 of the first conductivity type located on the back surface of i-type non-single-crystal film 5 exposed through non-single-crystal film 6 of the second conductivity type.

An alkali-resistant resist capable of deterring etching with the use of an alkali solution which will be described later is employed as second mask material 9. A conventionally known alkali-resistant resist can be employed as the alkali-resistant resist, without particularly being limited. For example, a photoresist for i rays or a photoresist for g rays manufactured by Tokyo Ouka Kogyo., Ltd. or a photoresist for TFT-LCD array etching for a liquid crystal display manufactured by JSR Corporation can be employed as the alkali-resistant resist.

Though a method of disposing second mask material 9 is not particularly limited, when second mask material 9 is made of an alkali-resistant resist, second mask material 9 can be disposed on the back surface of a part of non-single-crystal film 8 of the first conductivity type, for example, by applying second mask material 9 onto the entire back surface of non-single-crystal film 8 of the first conductivity type and thereafter patterning second mask material 9 with a photolithography technique and an etching technique.

Then, as shown in FIG. 12, non-single-crystal film 8 of the first conductivity type exposed through second mask material 9 is removed and thereafter second mask material 9 is removed.

Here, non-single-crystal film 8 of the first conductivity type is preferably removed, for example, through etching with the use of an alkali solution. Since the alkali solution is very high in rate of etching of an n-type non-single-crystal film of n-type amorphous silicon and very low in rate of etching of a p-type non-single-crystal film of p-type amorphous silicon, non-single-crystal film 8 of the first conductivity type can efficiently be removed and non-single-crystal film 6 of the second conductivity type which underlies non-single-crystal film 8 of the first conductivity type can function as an etching stop layer, and hence a part of non-single-crystal film 8 of the first conductivity type which is not covered with second mask material 9 can reliably be removed.

For example, a developer which contains potassium hydroxide or sodium hydroxide and is used for photolithography can be employed as the alkali solution.

Then, as shown in FIG. 1, electrode 13 for the first conductivity type is formed by stacking first electrode layer 10 and second electrode layer 11 in this order on non-single-crystal film 8 of the first conductivity type, and electrode 12 for the second conductivity type is formed by stacking first electrode layer 10 and second electrode layer 11 in this order on non-single-crystal film 6 of the second conductivity type. The hetero junction back contact cell in the embodiment having the structure shown in FIG. 1 is thus completed.

A conductive material can be employed for first electrode layer 10, and for example, indium tin oxide (ITO) can be employed.

A conductive material can be employed for second electrode layer 11, and for example, aluminum can be employed.

First electrode layer 10 and second electrode layer 11 can be formed, for example, by using a metal mask provided with an opening so as to expose the back surface of non-single-crystal film 6 of the second conductivity type and the back surface of non-single-crystal film 8 of the first conductivity type and successively stacking first electrode layer 10 and second electrode layer 11 with sputtering.

Though a thickness of first electrode layer 10 and a thickness of second electrode layer 11 are not particularly limited here, a thickness of first electrode layer 10 can be, for example, not greater than 80 nm and a thickness of second electrode layer 11 can be, for example, not greater than 0.5 μm.

As set forth above, the hetero junction back contact cell in the embodiment can be completed without removal of i-type non-single-crystal film 5 and exposure of the back surface of semiconductor substrate 1 after i-type non-single-crystal film 5 is once stacked on the entire back surface of semiconductor substrate 1. Therefore, since the hetero junction back contact cell in the embodiment can be manufactured while the back surface of semiconductor substrate 1 is prevented from being contaminated until completion thereof, capturing of carriers at the interface between the back surface of semiconductor substrate 1 and i-type non-single-crystal film 5 due to contamination of the back surface of semiconductor substrate 1 can be deterred. Since the hetero junction back contact cell in the embodiment can thus avoid shorter lifetime of carriers at the interface between the back surface of semiconductor substrate 1 and i-type non-single-crystal film 5, characteristics thereof are improved.

Since the back surface of semiconductor substrate 1 on which i-type non-single-crystal film 5 is stacked is flat in the hetero junction back contact cell in the embodiment, from this point of view as well, capturing of carriers at the interface between the back surface of semiconductor substrate 1 and i-type non-single-crystal film 5 can be deterred and shorter lifetime of carriers can be deterred, and hence characteristics are improved.

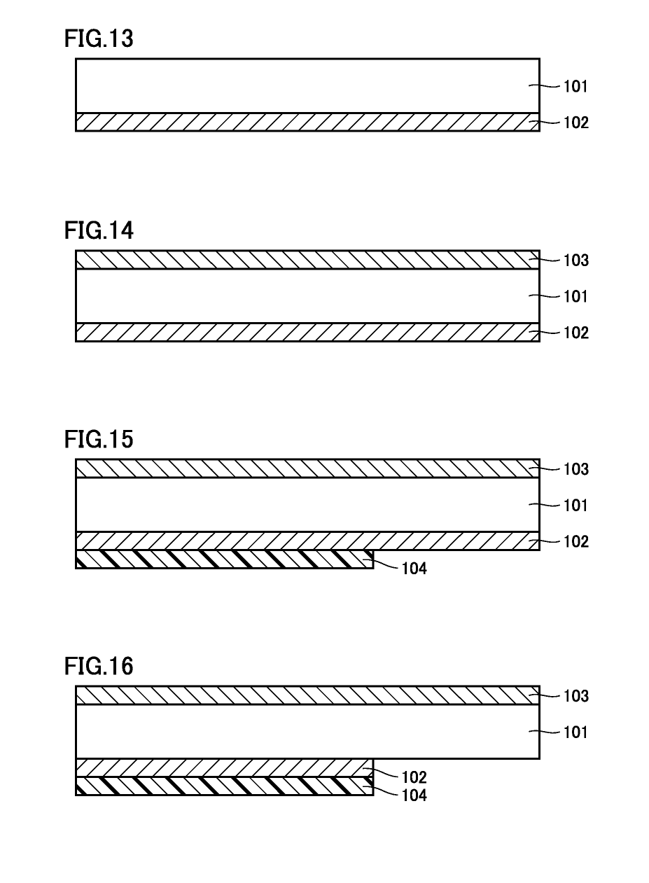

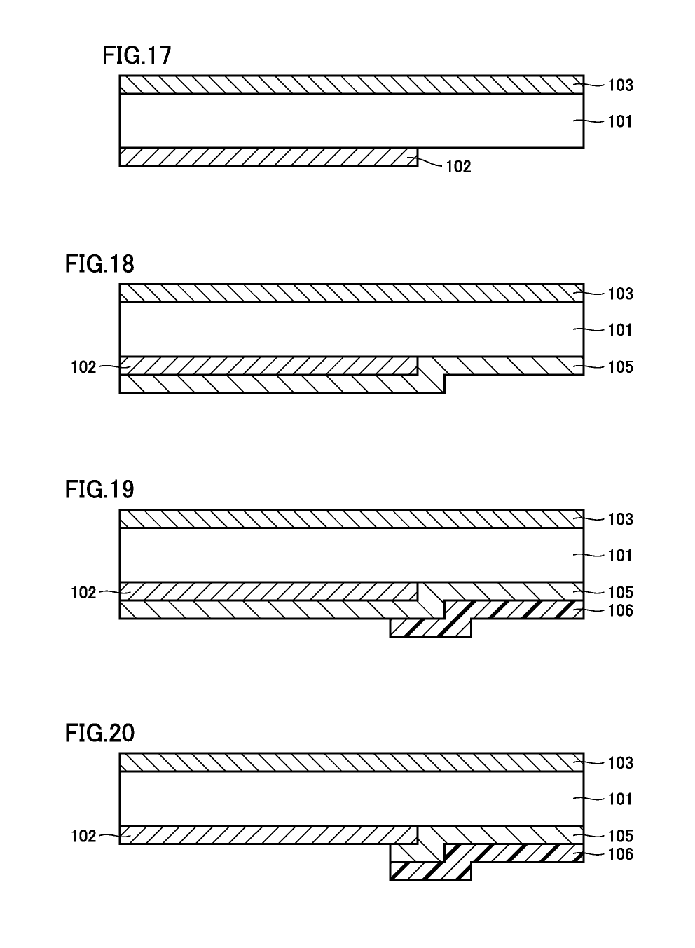

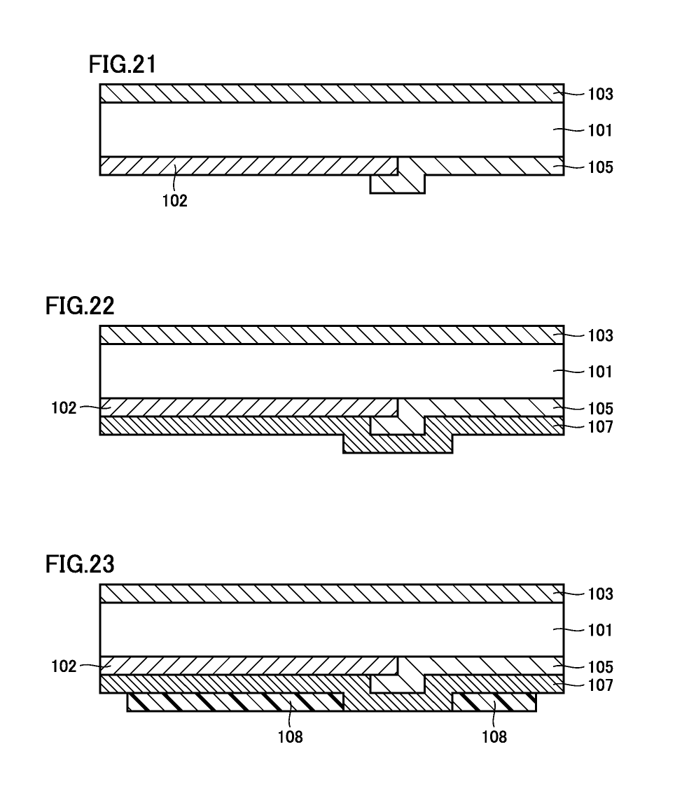

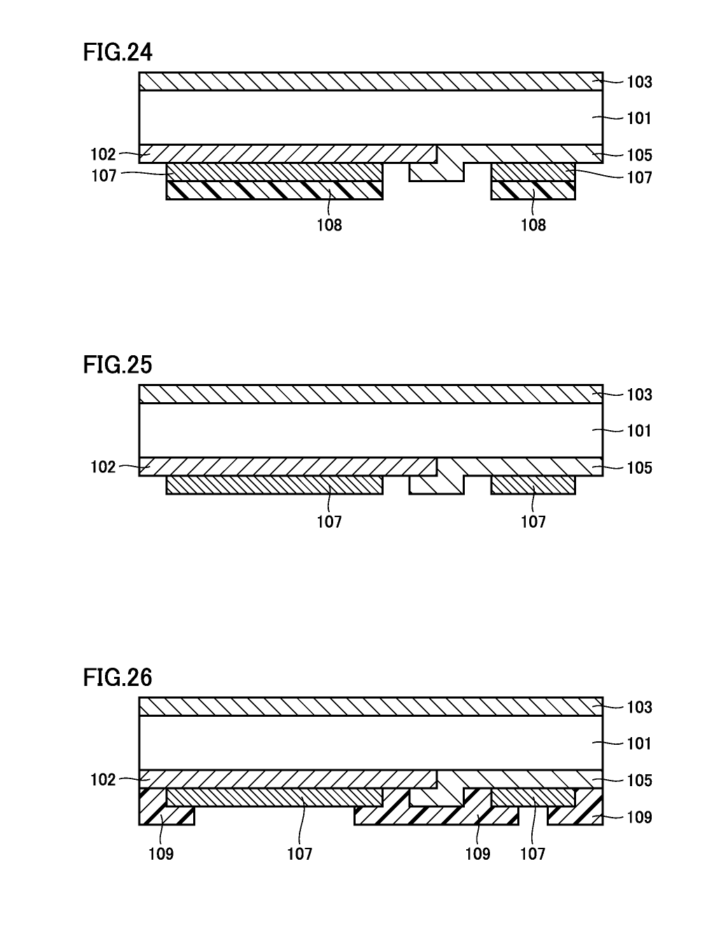

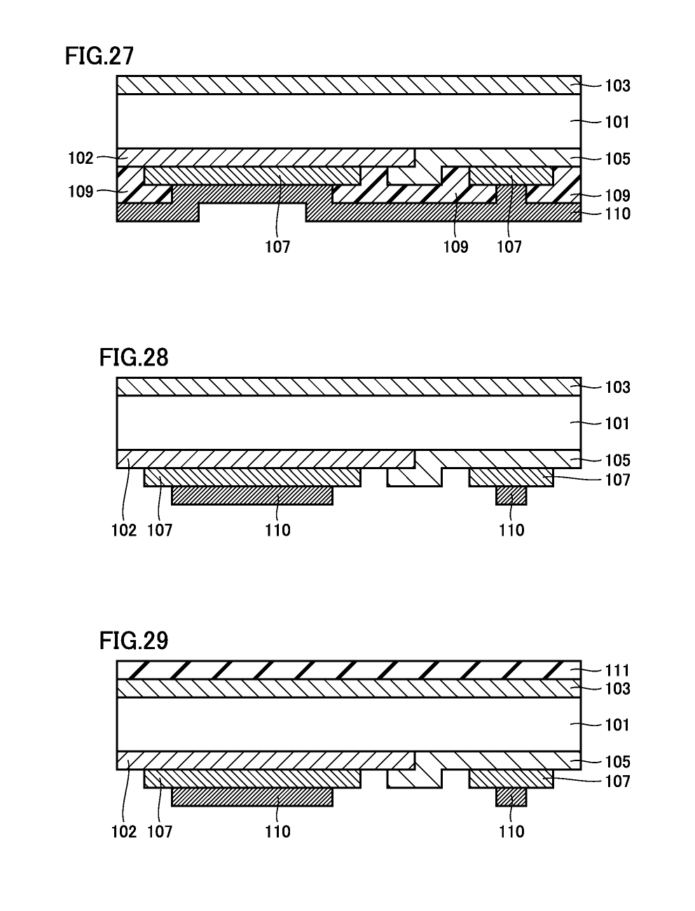

Furthermore, according to the method of manufacturing a hetero junction back contact cell in the embodiment, it is not necessary to perform the steps of application of a photoresist and patterning of a photoresist with the photolithography technique and the etching technique as many as four times as in the method shown in FIGS. 13 to 29, and hence the hetero junction back contact cell can be manufactured with a more simplified manufacturing process.

In particular in the method of manufacturing a hetero junction back contact cell in the embodiment, when a part of non-single-crystal film 8 of the first conductivity type is removed through etching with the use of an alkali solution after non-single-crystal film 8 of the first conductivity type is stacked to cover the back surface of i-type non-single-crystal film 5 and the back surface of non-single-crystal film 6 of the second conductivity type, non-single-crystal film 6 of the second conductivity type functions as the etching stop layer and hence non-single-crystal film 8 of the first conductivity type can efficiently and reliably be removed.

It should be understood that the embodiment disclosed herein is illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

The present invention can be made use of for a photoelectric conversion element and a method of manufacturing a photoelectric conversion element, and in particular, can suitably be made use of for a hetero junction back contact cell and a method of manufacturing a hetero junction back contact cell.

### REFERENCE SIGNS LIST

1 semiconductor substrate; 2 second i-type non-single-crystal film; 3 second non-single-crystal film of the first conductivity type; 4 anti-reflection coating; 5 i-type non-single-crystal film; 6 non-single-crystal film of the second conductivity type; 7 mask material; 8 non-single-crystal film of the first conductivity type; 9 second mask material; 10 first electrode layer; 11 second electrode layer; 12 electrode for the second conductivity type; 13 electrode for the first conductivity type; 14 interface; 101 c-Si (n) substrate; 102 a-Si (i/p) layer; 103 a-Si (i/n) layer; 104 photoresist film; 105 a-Si (i/n) layer; 106 photoresist film; 107 transparent conductive oxide film; 108, 109 photoresist film; 110 back electrode layer; and 111 anti-reflection coating.

1. A photoelectric conversion element, comprising:
a semiconductor substrate of a first conductivity type;
an i-type non-single-crystal film provided on entire one surface of said semiconductor substrate;
a non-single-crystal film of the first conductivity type provided on a surface of a part of said i-type non-single-crystal film;
a non-single-crystal film of a second conductivity type provided on the surface of another part of said i-type non-single-crystal film;
an electrode for the first conductivity type provided on said non-single-crystal film of the first conductivity type; and
an electrode for the second conductivity type provided on said non-single-crystal film of the second conductivity type,
an interface between said semiconductor substrate and said i-type non-single-crystal film being flat.

2. The photoelectric conversion element according to claim 1, wherein
said i-type non-single-crystal film is an i-type amorphous film.

3. The photoelectric conversion element according to claim 1, wherein
a maximum height difference in a proximate region around the interface between said semiconductor substrate and said i-type non-single-crystal film is smaller than 1 μm.

4. The photoelectric conversion element according to claim 1, wherein
said i-type non-single-crystal film between said non-single-crystal film of the first conductivity type and said semiconductor substrate is different in film thickness from said i-type non-single-crystal film between said non-single-crystal film of the second conductivity type and said semiconductor substrate.

5. The photoelectric conversion element according to claim 1, wherein
said i-type non-single-crystal film between said non-single-crystal film of the first conductivity type and said semiconductor substrate is smaller in film thickness than said i-type non-single-crystal film between said non-single-crystal film of the second conductivity type and said semiconductor substrate.

6. A method of manufacturing a photoelectric conversion element, comprising the steps of:
stacking an i-type non-single-crystal film on entire one surface of a semiconductor substrate of a first conductivity type;
stacking a non-single-crystal film of a second conductivity type on a surface of said i-type non-single-crystal film;
placing a mask material on a surface of a part of said non-single-crystal film of the second conductivity type;
removing said non-single-crystal film of the second conductivity type exposed through said mask material such that at least a part of said i-type non-single-crystal film is left;
forming a non-single-crystal film of the first conductivity type on the surface of said non-single-crystal film of the second conductivity type and on the surface of said i-type non-single-crystal film;
removing said non-single-crystal film of the first conductivity type on said surface of said non-single-crystal film of the second conductivity type such that a part of said non-single-crystal film of the first conductivity type is left on the surface of said i-type non-single-crystal film; and
forming an electrode layer on the surface of said non-single-crystal film of the first conductivity type and on the surface of said non-single-crystal film of the second conductivity type.

7. The method of manufacturing a photoelectric conversion element according to claim 6, wherein
said step of removing said non-single-crystal film of the first conductivity type is performed with wet etching using an alkali solution.

8. The method of manufacturing a photoelectric conversion element according to claim 6, wherein
said step of stacking an i-type non-single-crystal film is performed only once.

9. The method of manufacturing a photoelectric conversion element according to claim 6, wherein
said i-type non-single-crystal film is an i-type amorphous film.

10. The method of manufacturing a photoelectric conversion element according to claim 6, wherein
in said step of stacking an i-type non-single-crystal film, said i-type non-single-crystal film is formed on flat said surface of said semiconductor substrate.
